(19) United States
(12) Patent Application Publication
(10) Pub. No.: US 2025/0240898 A1
(43) Pub. Date: Jul. 24, 2025

(54) MANUFACTURING METHOD OF ELECTRONIC DEVICE

(71) Applicant: InnoLux Corporation, Miao-Li County (TW)

(72) Inventors: Chun-Hung CHEN, Miao-Li County (TW); Yu-Feng Lin, Miao-Li County (TW); Yung-Chieh Tseng, Miao-Li County (TW); Fu-Te Hsu, Miao-Li County (TW)

(73) Assignee: InnoLux Corporation, Miao-Li County (TW)

(21) Appl. No.: 19/001,433

(22) Filed: Dec. 25, 2024

(30) Foreign Application Priority Data
Jan. 24, 2024 (CN) 202410097298.6

(51) Int. Cl. H05K 3/46; H05K 3/00

(52) U.S. Cl. CPC H05K 3/4644; H05K 3/0017; H05K 3/0052; H05K 3/4602; H05K 3/4626; H05K 2203/0228; H05K 2203/0502; H05K 2203/107

(57) ABSTRACT

A release layer is on s substrate, and a circuit structure on the release layer. Providing the circuit structure includes a first conductive layer on the release layer, a first insulating layer on the first conductive layer and the release layer, a second conductive layer on the first insulating layer to electrically connect the first conductive layer through the via of the insulating layer, and a second insulating layer on the second conductive layer. A first patterning step is performed on the second insulating layer to form a first opening exposing the first insulating layer. A second patterning step is performed on the first insulation layer to form a second opening. In a cross-section of the electronic device, the second opening overlaps the first opening, the first opening width is smaller than the second opening width, the first opening exposes the surface of the first insulating layer.

### BACKGROUND OF THE DISCLOSURE

### 1. Field of the Disclosure

The present disclosure relates to a method of manufacturing an electronic device, in particular to a method of manufacturing an electronic device having a circuit structure.

### 2. Description of the Prior Art

In the manufacturing process of electronic devices, it is needed to dispose a circuit structure on a substrate, then a laser step is carried out on the circuit structure to expose a cutting line, and followed by a cutting step. After the laser step, the circuit structure adjacent to the cutting line would generate a warpage stress. As the circuit structures pile up more and more, the warpage stress becomes more significant to make peeling pone to occur in the circuit structure and between layers to jeopardize the process yield of the electronic devices.

In view of these, there is a need in this field to come up with a method of manufacturing an electronic device to improve the above problems.

### SUMMARY OF THE DISCLOSURE

Some embodiments of the present disclosure provide a method of manufacturing an electronic device. A substrate is provided to dispose a release layer on the substrate. A circuit structure is disposed on the release layer. Disposing the circuit structure on the release layer includes disposing a first conductive layer on the release layer, disposing a first insulating layer on the first conductive layer and on the release layer, disposing a second conductive layer on the first insulating layer to electrically connect the second conductive layer through a via of the first insulating layer to the first conductive layer, disposing a second insulating layer on the second conductive layer, and carrying out a first patterning step on the second insulating layer to form a first opening which exposes a portion of the first insulating layer. Then a second patterning step is carried out on the portion of the first insulating layer which is exposed by the first opening to form a second opening. In a cross-section of the electronic device, the second opening overlaps the first opening, a width of the second opening is smaller than a width of the first opening, and the first opening exposes an upper surface of the portion of the first insulating layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 illustrates a schematic top view of a substrate according to some embodiments of a method of forming an electronic device of the present disclosure.

FIG. 2 to FIG. 6 respectively illustrate a process schematic diagram of a method for forming an electronic device according to the present disclosure.

FIG. 7 to FIG. 9 respectively illustrate a schematic diagram of a variant embodiment of a method of forming an electronic device according to the present disclosure.

FIG. 10 illustrates a partial flow diagram of a process corresponding to some methods of forming an electronic device of the present disclosure.

FIG. 11 to FIG. 13 respectively illustrate a schematic top view of an electronic device of some embodiments of a method of forming the electronic device according to the present disclosure.

FIG. 14 illustrates a schematic process diagram of a method of forming an electronic device according to the present disclosure.

FIG. 15 illustrates a schematic cross-sectional view of a variant embodiment of the electronic device.

### DETAILED DESCRIPTION

The present disclosure may be understood by reference to the following detailed description, taken in conjunction with the drawings as described below. For purposes of illustrative clarity understood, various drawings of this disclosure show a portion of the electronic device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not in function. The following description lists various embodiments of the present disclosure to elaborate the basic concepts of the present disclosure, and is not intended to limit the scope of the present disclosure. The actual scope of the present disclosure should be defined according to the scope of the accompanied claims. Exemplary embodiments of the present disclosure are given in detail, and examples of the exemplary embodiments are illustrated in the accompanying drawings. Whenever possible, the same reference numbers are used in the drawings and in the descriptions to refer to the same or similar parts.

The directional terms mentioned in this article, such as: “up”, “down”, “front”, “back”, “left”, “right”, etc., are only for reference to the directions in the accompanying drawings. Accordingly, the directional terms used are for illustrative purpose only and not for limiting the disclosure. In the drawings, each figure illustrates the general features of methods, structures, and/or materials used in particular embodiments. However, these drawings should not be interpreted as defining or limiting the scope or the nature encompassed by these embodiments. For example, the relative sizes, thicknesses, and locations of various layers, regions, and/or structures may be reduced or exaggerated for clarity. The present disclosure may be understood by referring to the following detailed descriptions in combination with the accompanying drawings. It should be noted that, in order to make it easy for readers to understand and for the simplicity of the drawings, multiple drawings in the present disclosure only depict a part of the electronic device. And certain elements in the drawings are not drawn to actual scale. In addition, the number and size of components in the figures are for illustrative purpose only and are not intended to limit the scope of the present disclosure.

In the following description and in the claims, the terms “include”, “comprise” and “have” are used in an open-ended fashion, and thus should be interpreted to mean “include, but not limited to . . . ”.

It should be understood that when an element or layer is referred to as “on another component or on another layer” or “connected to another component or to another layer”, it may be directly on or directly connected to the other element or layer, or intervening elements or layers may be presented. In contrast, when an element is referred to as “directly on” or “directly connected to” another element or layer, there are no intervening elements or layers presented.

In some embodiments of the present disclosure, terms such as “connection”, “interconnection”, etc. regarding bonding and connection, unless specifically defined, may refer to two structures which are in direct contact with each other, or are not in direct contact with each other. It is possible that there are other structures located between these two structures. Moreover, terms such as “connection”, “interconnection” may also include the case where both structures are movable or both structures are fixed. In addition, the terms “electrical connected” or “electrical coupled” includes any direct and indirect electrical connection means.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which elements are claimed. Accordingly, in the following description, a first constituent element may be a second constituent element in a claim.

In the following description, roughness is defined as: when observed with a scanning electron microscope (SEM), on the surface of a given component, it may be seen that the peaks and valleys of surface have a distance difference of 0.15 μm to 0.5 μm. Measurement of the roughness may include using a scanning electron microscope, a transmission electron microscope (TEM), etc. to observe the surface undulations at the same appropriate magnification to compare the undulations by capturing unit length (for example, 10 μm). Here, “appropriate magnification” means that at least 10 undulating peaks are observed on at least one surface under the field of view at this magnification. The distance between the above-mentioned components may be measured, for example, by using a scanning electron microscope ruler on a cross-sectional view.

It should be noted that the technical features in different embodiments described in the following may be redisposed, recombined, or mixed with one another to constitute another embodiment without departing from the spirit of the present disclosure.

The terms “about”, “equal to”, “equals” or “the same”, “substantially” or “generally” are usually interpreted to mean within 20% of a given value or range, or to mean within 10%, 5%, 3%, 2%, 1% or 0.5% of a given value or range. In the present disclosure, the terms “a given range is a first value to a second value” and “a given range within a range of a first value to a second value” mean that the given range includes the first value, the second value values and other values between them.

Furthermore, any two numerical values or directions used for comparison may have certain errors. If the first value is equal to the second value, it implies that there may be an error of about 10% between the first value and the second value. If the first direction is perpendicular or “approximately” perpendicular to the second direction, then an angle between the first direction and the second direction may be between 80 degrees and 100 degrees. If the first direction is parallel or “substantially” parallel to the second direction, the angle between the first direction and the second direction may be between 0 degree and 10 degrees.

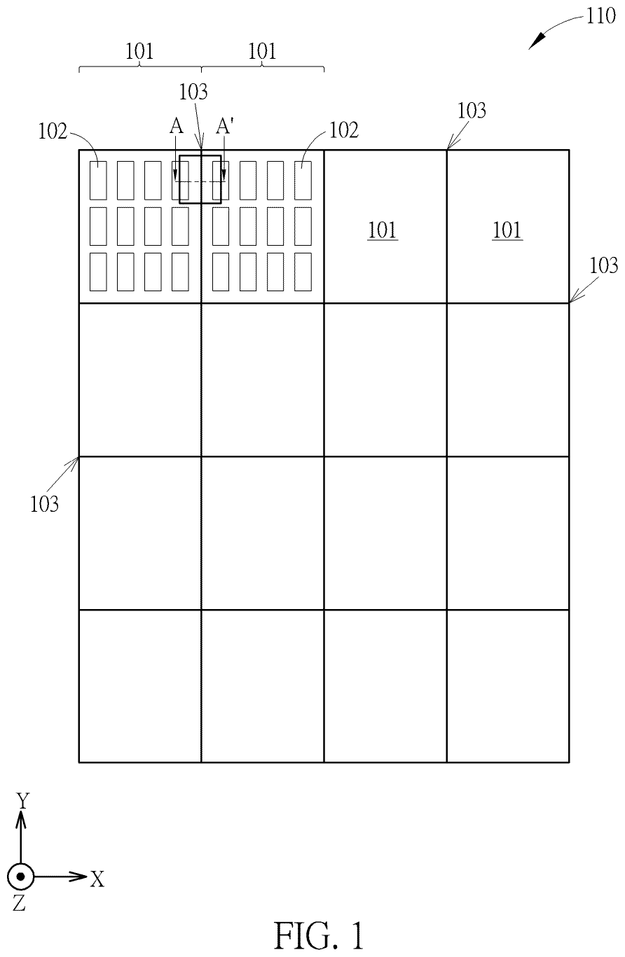

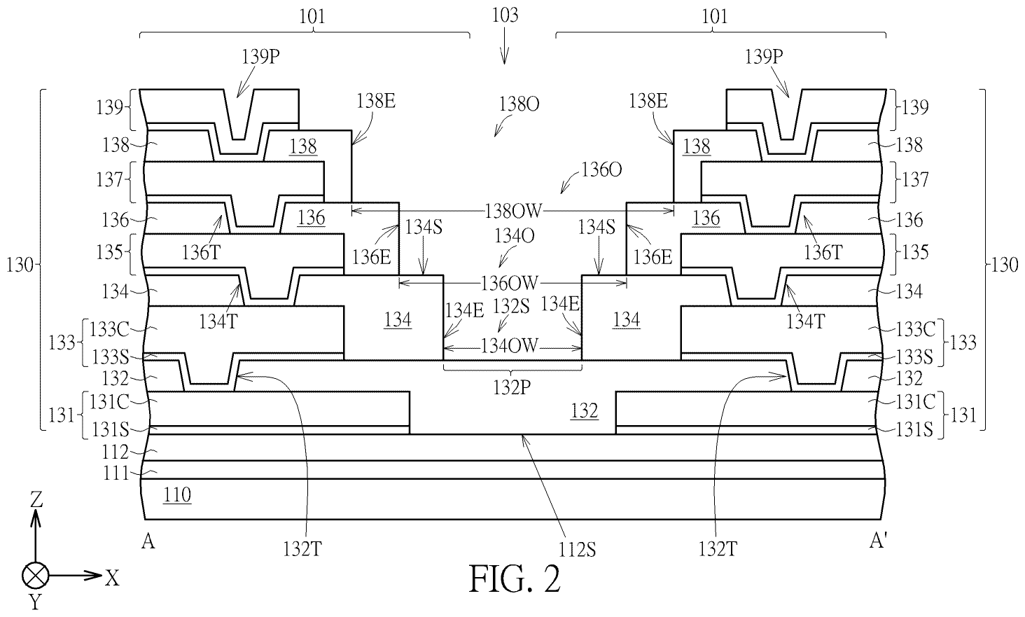

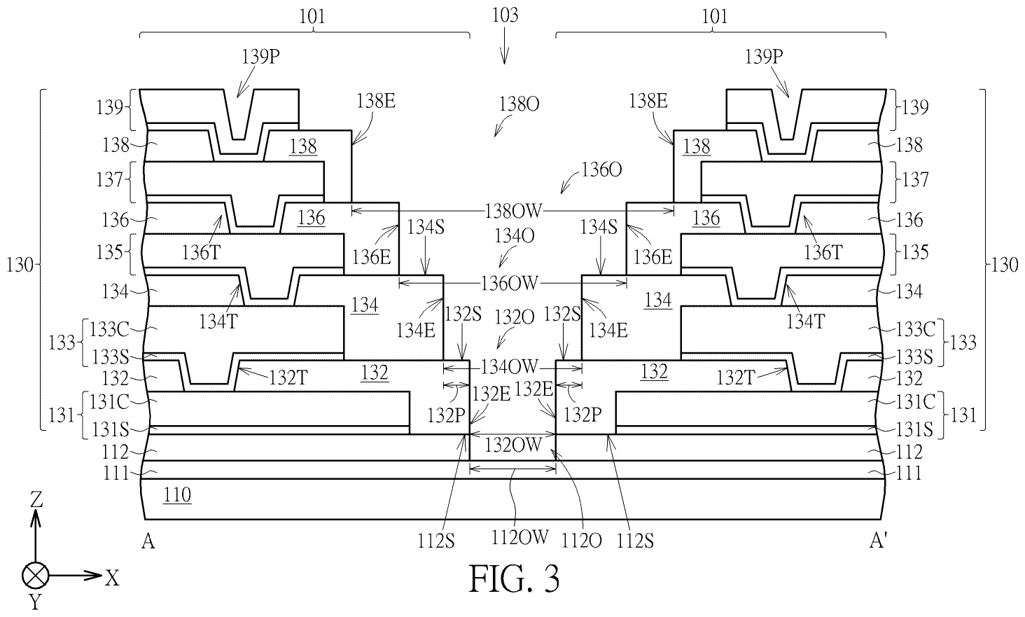

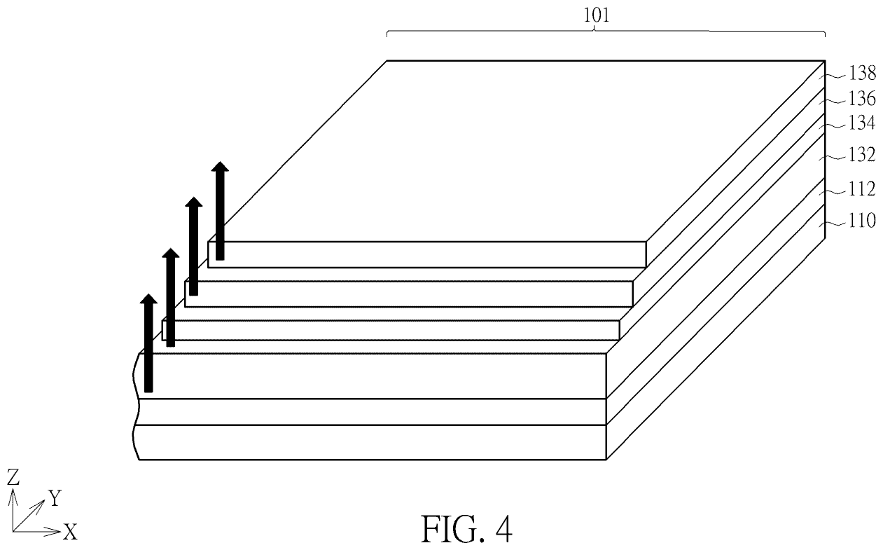

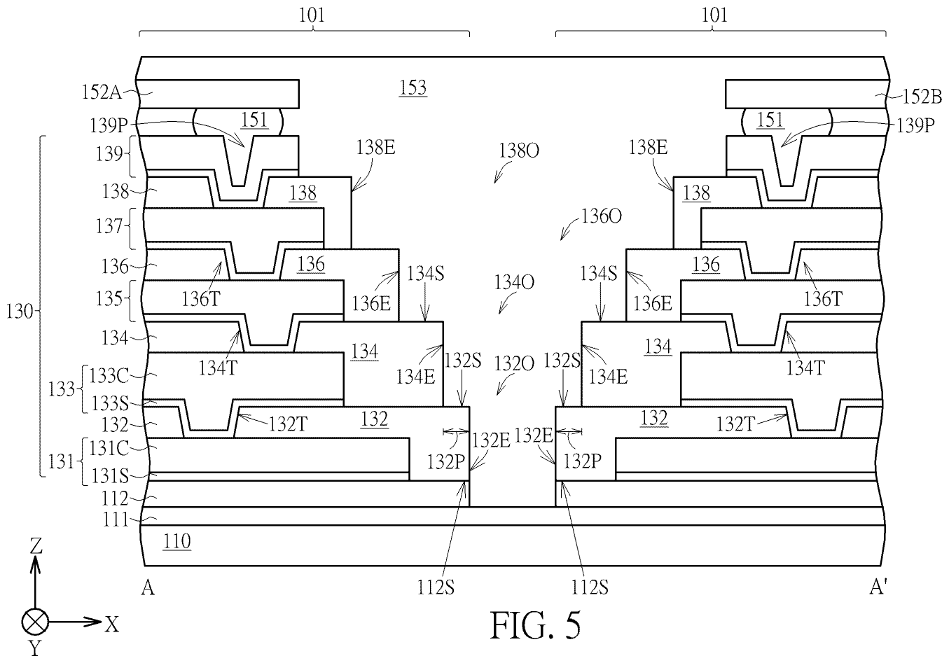

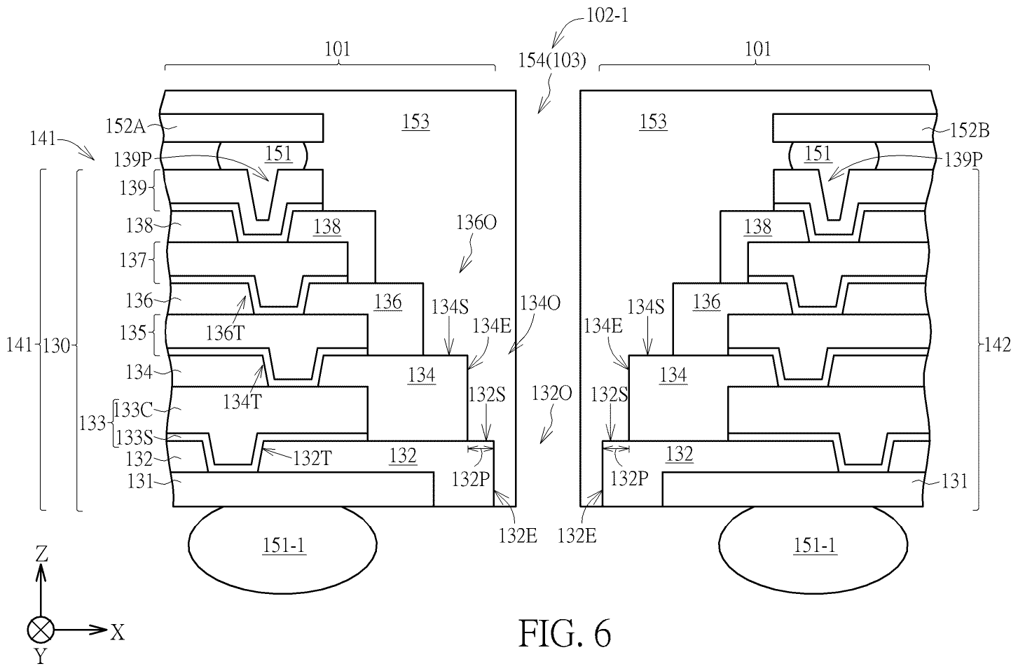

FIG. 1 illustrates a schematic top view of a substrate 110 (motherboard) according to some embodiments of a method of forming an electronic device of the present disclosure. FIG. 2 to FIG. 6 respectively illustrate a process schematic diagram of a method for forming an electronic device according to the present disclosure. FIG. 2, FIG. 3, FIG. 5 and FIG. 6 respectively illustrate the component structures in a cross-sectional schematic view. FIG. 4 illustrates a perspective view corresponding to the component structures between the sub-plates shown in FIG. 3. An electronic unit of the present disclosure may be applied to a power module, a semiconductor packaging device, a display device, a light-emitting device, a backlight device, an antenna device, a sensing device, a vehicle device or a splicing device, but the present disclosure is not limited thereto. In the present disclosure, the electronic device may include various electronic elements, a semiconductor packaging element, a display device, a light-emitting device, a sensing device, an antenna device, a foldable electronic device, a splicing device or a flexible electronic device, but the present disclosure is not limited thereto. The electronic devices may include a semiconductor die, or piles formed by staggered stacks of multiple metal layers (copper layers and seed layers) and multiple insulating layers, such as a redistribution layer (RDL), but they are not limited to these. “Flexible/foldable” here refers to materials which may be curved, bent, folded, rolled, flexible, stretched and/or other similar deformations, to represent at least one possible deformation method mentioned above, and “flexibility/foldability” is not limited to the above-mentioned deformation methods. The antenna device may be a liquid crystal type antenna device or a non-liquid crystal type antenna device, and the sensing device may be a sensing device which senses capacitance, light, heat energy or ultrasonic waves, but the present disclosure is not limited thereto. Electronic components may include passive components, active components, or a combination of the above, such as a capacitor, a resistor, an inductor, a varactor diode, a variable capacitor, a filter, a diode, a transistor, a sensor, a microelectromechanical system component (MEMS), a liquid crystal chip, etc., but they are not limited to these. A diode may include a light-emitting diode or a non-light-emitting diode. The diode may include a P-N junction diode, a PIN diode or a constant current diode. A light-emitting diode may include an organic light-emitting diode (OLED), a sub-millimeter light-emitting diode (mini LED), a micro light-emitting diode (micro LED), a quantum dot light-emitting diode (QLED), a fluorescent diode, a phosphor diode, or other suitable materials, or an optional combination of these materials, but the present disclosure is not limited thereto. A sensor may include, for example, a capacitive sensor, an optical sensor, an electromagnetic sensor, a fingerprint sensor (FPS, a touch sensor, an antenna, or stylus pen, etc., but they are not limited to these. An electronic component may include a die or a light-emitting diode die (LED die), a die made of silicon (Si), gallium arsenide (GaAs), gallium nitride (GaN), silicon carbide (Sic), sapphire or a glass substrate, but the present disclosure is not limited thereto. In one embodiment, the die may include a semiconductor packaging component, such as a ball grid array (BGA) packaging component, a chip size package (CSP) component, a flip chip or 2.5-dimensional/3-dimensional (2.5D/3D) semiconductor packaging components, but they are not limited to these. In another embodiment, the die may be any flip-chip bonded component, such as an integrated circuit (IC), a transistor, a controlled silicon rectifier, a valve, a thin film transistor, a capacitor, an inductor, a variable capacitor, or a filter device, a resistor, a diode, a microelectromechanical system components (MEMS), a liquid crystal die, etc., but they are not limited to these. The die may include, for example, a diode or a semiconductor die, but the present disclosure is not limited thereto. The die may be a known good die (KGD), which may include various electronic components, such as (but not limited to) wires, transistors, circuit boards. Adjacent dies may have different functions, such as integrated circuits, RFIC, and D-RAM, but the present disclosure is not limited thereto.

If the electronic device is applied to packaging, it may be suitable for a panel level packaging (PLP), a ball grid array packaging (BGA), a chip size packaging (CSP), a chip on wafer on substrate (CoWoS), for example, may include a chip-first or a redistribution layer first (RDL first) packaging method, but the present disclosure is not limited thereto. It should be noted that the electronic device may be any combination of the above, but the present disclosure is not limited thereto. Each example of the present disclosure illustrates a combination of a plurality of electronic units, a RDL structure, a metal layer, an insulating layer, a stud, a bonding component and an input/output bonding pad (I/O pad). The electronic unit of the present disclosure may be an example of an electronic device of a fan-out package, but the present disclosure is not limited thereto. In the following, a packaging device is used as an example of an electronic device to elaborate the present disclosure, but the present disclosure is not limited thereto. The dielectric material of the circuit redistribution layer may include an organic dielectric material, an inorganic dielectric material, or a combination of the above and other dielectric materials which may be used for packaging, but the present disclosure is not limited thereto. The organic dielectric materials for example include polybenzoxazole (PBO), benzocyclobutene (BCB), acrylic, ABF carrier, polyimide (PI), polyamide amine, other suitable materials, or a combinations thereof used as the organic dielectric material for encapsulation, but the present disclosure is not limited thereto. The inorganic dielectric material may include, for example, silicon oxide, silicon nitride, aluminum oxide, siloxane, other suitable materials, or a combination thereof for use in packaging, but the present disclosure is not limited thereto.

The X direction and the Y direction shown in FIG. 1 represent the plane direction of the substrate 110 (motherboard). The Z direction in FIG. 2 is the normal direction of the substrate 110. The X direction and the Y direction are respectively perpendicular to the Z direction. Please refer to FIG. 1, a method of manufacturing an electronic device includes providing a substrate 110 (motherboard). The substrate 110 includes a plurality of sub-plate regions (such as the sub-plate regions 101). Each sub-plate regions 101 of the substrate 110 in FIG. 1 may include a plurality of component regions 102 and, for example, they are arranged in a form of a matrix or in other suitable manner, but the present disclosure is not limited thereto. A cutting line 103 is disposed between adjacent sub-plate regions 101. The cutting line 103 may roughly define the cutting positions of subsequent adjacent sub-plate regions 101, but the present disclosure is not limited thereto. Other cutting lines (not labeled) may be disposed between adjacent sub-plate regions 101.

Please continue to refer to FIG. 2. FIG. 2 illustrates a schematic cross-sectional view of two adjacent sub-plate regions 101 in the substrate 110 shown in FIG. 1 along the A-A′ line according to some embodiments of a method of forming an electronic device of the present disclosure to show component piles in adjacent component regions 102 of different sub-plate regions 101. Specifically speaking, the manufacturing method of the electronic device includes providing a substrate (or a carrier) 110, disposing a release layer 112 on the substrate 110, and disposing a circuit structure 130 on the release layer 112. In some embodiments (not shown), a warpage reduction device may be optionally used to suppress the warpage of the structure, and then the circuit structure 130 is formed by processes such as film deposition, acid etching, alkali etching, surface treatment, plasma treatment, lithographic exposure and/or laser before disposing the circuit structure 130 (redistribution layer), but the present disclosure is not limited thereto.

In some embodiments, before disposing the release layer 112 on the substrate 110, a warpage anti layer 111 may be disposed on the substrate 110, that is, the warpage anti layer 111 is, for example, disposed between the substrate 110 and the release layer 112, but the present disclosure is not limited thereto. In some embodiments, the warpage anti layer 111 is in contact with the substrate 110 and/or the release layer 112, for example, but the present disclosure is not limited thereto. In some embodiments, the warpage anti layer 111 may be disposed on one side of the substrate 110 or on two opposite sides and may optionally contact the substrate 110 to reduce the wapage of the substrate 110 and the piles thereon caused during the manufacturing process of the electronic device. The release layer 112 is disposed between the warpage anti layer 111 and the circuit structure 130. In some embodiments, the surface of the release layer 112 may be optionally treated with micro-etching. The micro-etching process may increase the roughness of the surface of the release layer 112 to improve the adhesion with the above-mentioned piles.

In some embodiments, the substrate 110 includes, for example, a supportive substrate, such as an organic material substrate or an inorganic material substrate, such as a glass substrate, a ceramic substrate, a plastic substrate, a copper substrate, a steel plate, or a polyimide (PI) substrate, a polyethylene terephthalate (PET) substrate, a wafer or other suitable materials or a combination of the above. The top view shape of the substrate 110 may be rectangle, square, circle, polygon or a free-shape, but the present disclosure is not limited thereto. The warpage anti layer 111 may include an inorganic material, such as silicon nitride or other suitable material layers, to reduce the degree of warpage of the electronic device. The thickness of the warpage anti layer 111 may be in a range from 500 angstroms to 1500 angstroms (500 angstroms≤thickness≤1500 angstroms) or between 600 angstroms and 1400 angstroms (600 angstroms≤thickness≤1400 angstroms) or between 650 angstroms and 1350 angstroms (650 angstroms≤thickness≤1350 angstroms), but the present disclosure is not limited thereto. The release layer 112 may be a temporary adhesive layer or other suitable material layer so that the circuit structure 130 may be temporarily attached to the warpage anti layer 111 and/or to the substrate 110. The release layer 112 may be, for example, illuminated by specific light, or it may be heated to change the adhesion of the release layer 112 to facilitate peeling off the circuit structure 130 from the substrate 110, but the present disclosure is not limited thereto. The “release layer” mentioned in this disclosure may include an adhesive material, such as an adhesive material which may be separated by laser, light or thermal cracking, but the present disclosure is not limited thereto.

In some embodiments, the circuit structure 130 may serve as a redistribution layer (RDL). The circuit structure 130 may be electrically connected to various electronic components through bonding pads, and may include at least one conductive layer and at least one insulating layer. For example, the circuit structure 130 may increase the fan-out area of the circuit, or different electronic components may be electrically connected to one another via the circuit structure 130. According to some embodiments, the circuit structure 130 includes at least a first conductive layer 131, a first insulating layer 132, a second conductive layer 133 and a second insulating layer 134, and optionally includes more conductive layers and insulating layers. These material layers form a pile structure by stacking along the Z direction.

Please refer to FIG. 2. As mentioned above, the release layer 112 is disposed on the substrate 110, and the circuit structure 130 is disposed on the release layer 112. The step of disposing the circuit structure 130 includes disposing the first conductive layer 131 on the release layer 112. Then, the first insulating layer 132 is disposed on the first conductive layer 111 and on the release layer 112. Next, the second conductive layer 133 is disposed on the first insulating layer 132. The second conductive layer 133 may be electrically connected to the first conductive layer 131 through at least one via 132T in the first insulating layer 132. Then, the second insulating layer 134 may be disposed on the second conductive layer 133. Next, a first patterning step is carried out on the second insulating layer 134 to form a first opening 134O, and the first opening 134O may expose a portion 132P of the first insulating layer 132.

In some embodiments, the third conductive layer 135 is optionally disposed on the second insulating layer 134, and the third conductive layer 135 may be electrically connected to the second conductive layer 133 through at least one via 134T in the second insulating layer 134. Next, the third insulating layer 136 is disposed on the third conductive layer 135. In some embodiments, the first conductive layer 131, the second conductive layer 133, the third conductive layer 135 or other conductive layers in the circuit structure 130 includes, for example, a metal material or an alloy material. The above-mentioned conductive layers include, for example, a single layer or a multi-layer stack, such as include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials or any combination of the above. In some embodiments, the first insulating layer 132, the second insulating layer 134, the third insulating layer 136 or other insulating layers in the circuit structure 130 includes an organic material or an inorganic material, such as photosensitive polyimide (PSPI), polyethylene (PE), polyethylene terephthalate (PET), polycarbonate (PC), polytetrafluoroethylene (PTFE), polystyrene (PS), acrylonitrile-butadiene-styrene copolymer (ABS), other suitable materials, or any combination thereof, but the present disclosure is not limited thereto. In some embodiments, the first insulating layer 132, the second insulating layer 134, the third insulating layer 136 or other insulating layers in the circuit structure 130 may include, for example, but not limited to, polyimide, epoxy, silicon nitride (SiNx), silicon oxide (SiOx) or a combination of the above.

In detail, the method for manufacturing the circuit structure 130 may be, for example, firstly setting a seed layer 131S (for example, a seed layer including titanium, copper or nickel, but the present disclosure is not limited thereto) on the release layer 112, and then disposing a patterned photoresist layer (not shown) on the seed layer 131S. Then, a conductive layer 131C is disposed on the exposed seed layer 131S by electroplating or electroless plating. The conductive layer 131C may include a patterned conductive layer of copper, of nickel, of gold, of titanium, of molybdenum, of aluminum or of other suitable materials. Then, the patterned photoresist material (not shown) and the seed layer 131S underneath are removed. The photoresist material (not shown) includes an adhered dry film or a positive photoresist or a negative photoresist patterned by exposure and development to roughly define the pattern of the conductive layer 131C. The above-mentioned first conductive layer 131 may include a seed layer 131S and a conductive layer 131C. Next, the first insulating layer 132 is disposed on the first conductive layer 131, and at least one via 132T in the first insulating layer 132 is formed by lithographic etching. Then, a seed layer 133S is disposed on the surface of the first insulating layer 132, and the seed layer 133S and the conductive layer 133C are disposed and the second conductive layer 133 is obtained by a method similar to the first conductive layer 131. Next, the second insulating layer 134 is disposed on the second conductive layer 133, and at least one via 134T is formed in the second insulating layer 134 by similar lithographic etching. The above steps are optionally repeated one or more times to obtain the circuit structure 130 with the required number of conductive layers and insulating layers. The upper conductive layer may be electrically connected to the underlying conductive layer through at least one via in the underlying insulating layer.

Please continue to refer to FIG. 2. As mentioned above, a first patterning step is carried out on the second insulating layer 134 to form a first opening 134O, and the first opening 134O may expose a portion 132P of the first insulating layer 132. According to some embodiments, the first patterning step is, for example, a lithographic etching method, but the present disclosure is not limited thereto. According to some examples, the first opening 134O may expose the first insulating layer 132 (for example, a portion 132P of the first insulating layer 132) in contact with the release layer 112. In some embodiments, after optionally disposing the third conductive layer 135 on the second insulating layer 134, the third insulating layer 136 is disposed on the third conductive layer 135. After the third insulating layer 136 is disposed, for example, a third patterning step is carried out on the third insulating layer 136 to form the third opening 136O. In a cross-section of the electronic device, the third opening 136O may overlap the first opening 134O of the second insulation layer 134. The width 136OW of the third opening 136O is greater than the width 134OW of the first opening 134O, and the third opening 136O may expose a portion of the upper surface 134S of the second insulation layer 134. The width 136OW of the third opening 136O is, for example, the width of the third opening 136O adjacent to the second insulating layer 134 in the cross-section of the electronic device. The width 134OW of the first opening 134O is, for example, the width of the first opening 134O adjacent to the first insulating layer 132 in the cross-section of the electronic device. In some embodiments, in a cross-section of the electronic device, the side 134E of the second insulating layer 134 exposed by the first opening 134O may, for example, extend from at least one side 136E of the third insulating layer 136 exposed by the third opening 136O and they do not align with each other, but the present disclosure is not limited thereto. In other embodiments (not shown), at least one side 134E of the second insulating layer 134 exposed by the first opening 134O may roughly align with at least one side 136E of the third insulating layer 136 exposed by the third opening 136O, but the present disclosure is not limited thereto.

Continuing to refer to FIG. 3, after completing the first patterning step and/or the third patterning step, other conductive layers (such as a top conductive layer 137, a bonding conductive layer 139 or other conductive layers) and the insulating layer (such as a top insulating layer 138 or other insulating layers) may be formed in a similar manner according to the number of conductive layers and insulating layers required for the circuit structure 130, and at least one via may be formed in an insulating layer in a similar manner so an upper conductive layer may be electrically connected to the underlying conductive layer through the via in the underlying insulating layer. Similarly, after other insulating layers (such as the top insulating layer 138 or other insulating layers) are disposed, a patterning step may be optionally carried out to form other openings (not labeled) in other insulating layers. These other openings (such as the opening 138O in the top insulating layer 138) may overlap the first opening 134O of the second insulating layer 134. In the cross-section of the electronic device, the widths (for example, the width 138OW) of these other openings (for example, the opening 138O of the top insulating layer 138) may be optionally greater than or equal to the width 134OW of the first opening 134O. The width 136OW of the opening 138O is, for example, the width of the opening 138O adjacent to the third insulating layer 136 in a cross-section of the electronic device. These other openings (such as the opening 138O of the top insulating layer 138) may expose an upper surface 132S of the first insulating layer 132, but these other openings (such as the openings 138O of the top insulating layer 138) may or may not optionally expose the upper surface 134S of the second insulating layer 134. The stacked layers of the circuit structure 130 are generally formed by the above manner.

Subsequently, a second patterning step may be carried out on the portion 132P of the first insulation layer 132 which is exposed by the first opening 134O to form the second opening 132O. In a cross-section of the electronic device, the second opening 132O overlaps the first opening 134O, the width of the second opening 132O is smaller than the width of the first opening 134O, and the first opening 134O exposes the upper surface 132S of the portion 132P of the first insulating layer 132. The width 132OW of the second opening 132O is, for example, the width of the opening 132O away from the second insulating layer 134 in a cross-section of the electronic device. According to some examples, the first patterning step and/or the third patterning step for example uses different patterning methods from the second patterning step, but the present disclosure is not limited thereto. The first patterning step and/or the third patterning step uses a lithographic etching method, and the second patterning step may use a laser removal method, for example, but the present disclosure is not limited thereto. According to some examples, in a cross-section, at least one side 132E of the first insulating layer 132 exposed by the second opening 132O may extend from at least one side 134E of the second insulating layer 134 and the portion 132P of the first insulating layer 132 adjacent to the second opening 132O may contact the upper surface 112S of the release layer 112.

The above-mentioned patterning step may also optionally partially remove the release layer 112 to form the opening 112O. The opening 112O overlaps the second opening 132O, and the edge of the opening 112O may roughly align with the second opening 132O. The width 1220W of the opening 112O is, for example, the width of the opening 112O away from the first insulating layer 132 in a cross-section of the electronic device. In a cross-section, the width 132OW of the second opening 132O may be substantially the same as or different from the width 132OW of the second opening 132O, but the present disclosure is not limited thereto. The above-mentioned second patterning step may optionally not remove the warpage anti layer 111 which overlaps the second opening 132O and the substrate 110.

According to some embodiments, in a cross-section, the size (for example, width) of the first opening 134O along the X direction and/or the Y direction may be larger than the size (for example, the width) of the second opening 132O along the X direction and/or the Y direction. The X direction and/or the Y direction are, for example, directions parallel to the surface of the substrate 110, and the X direction is different from the Y direction. According to some embodiments, in a cross-section, the second opening 132O overlaps the first opening 134O, and the projection of the second opening 132O onto the substrate 110 is within the projection of the first opening 134O onto the substrate 110. In other words, in a cross-section, the first opening 134O may expose the upper surface 132S of the portion 132P of the first insulating layer 132.

According to some embodiments, in a cross-section, the third opening 136O overlaps the first opening 134O. In a cross-section, the third opening 136O exposes the upper surface 134S of the second insulating layer 134, that is, the projection of the first opening 134O projected onto the substrate 110 may be within the projection of the third opening 136O projected onto the substrate 110, but the present disclosure is not limited thereto.

Please continue to refer to FIG. 4. In order to simplify the representation of the structure, the warpage anti layer 111 and the conductive layers are omitted in FIG. 4, and only the insulating layers, the release layer 112 and the substrate 110 in the circuit structure 130 are shown. According to some examples, the first insulating layer 132, the second insulating layer 134, the third insulating layer 136 and the top insulating layer 138 may be sequentially disposed on the substrate 110 and on the release layer 112, and a step-like or a pyramid-like pile structure is formed by the above patterning steps, but the present disclosure is not limited thereto. From a top view direction of the electronic device, the areas of the first insulating layer 132, of the second insulating layer 134, of the third insulating layer 136 and of the top insulating layer 138 may, for example, gradually decrease sequentially, but the present disclosure is not limited thereto. The above-mentioned gradual decrease is, for example, equally proportional or non-equally proportional. Through the above-mentioned design of a step-like or of a pyramid-like pile structure, the warpage stress of each insulating layer in the circuit structure 130 may be distributed.

Please continue to refer to FIG. 5. After the second patterning step is completed, an electronic unit may be disposed or bonded on the circuit structure 130, and a packaging step may be carried out. For example, the bonding element 151 may be formed on the circuit structure 130, and the bonding element 151 may be electrically connected to the bonding conductive layer 139, and then multiple electronic units (such as the electronic unit 152A and the electronic unit 152B) are respectively arranged corresponding to different bonding elements 151. The electronic unit 152A and the electronic unit 152B may be electrically connected to different bonding conductive layers 139 via different bonding elements 151 respectively. The bonding elements 151 may be formed by ball drop and reflow steps, and some of the bonding elements 151 are, for example, disposed in the recess 139P of the bonding conductive layer 139. According to some embodiments, the bonding element 151 may include a bump or a solder ball, but the present disclosure is not limited thereto. In some examples, the bonding conductive layer 139 may include a rough surface, which is beneficial to increase the contact effect between the bonding elements 151 and the bonding conductive layer 139.

In some embodiments, after disposing the bonding elements 151 and the electronic units (electronic units 152A and 152B), an encapsulating material 153 for example may be disposed on the circuit structure 130 and on the electronic units (such as the electronic units 152A and 152B) and some of the encapsulating material 153 may contact the warpage anti layer 111 (or the substrate 110) through the openings (such as the above-mentioned first opening 134O, the second opening 132O, the third opening 136O, the opening 138O, but the present disclosure is not limited thereto) of the insulating layers of the circuit structure 130. In some examples, the encapsulating material 153 contacts, for example, the side 132E of the first insulating layer 132, the side 134E of the second insulating layer 134, the side 136E of the third insulating layer 136 and/or the side 138E of the top insulating layer 138, but the present disclosure is not limited thereto. In some examples, the encapsulating material 153 is filled, for example, into these openings (such as the above-mentioned first opening 134O, the second opening 132O, the third opening 136O, the opening 138O, but the present disclosure is not limited thereto) of the above-mentioned insulating layers of the circuit structure 130.

According to some embodiments, the encapsulating material 153 may cover the circuit structure 130, a plurality of bonding elements 151 and a plurality of the electronic units (such as the electronic unit 152A and the electronic unit 152B), so that the circuit structure 130, the bonding elements 151 and the electronic units (such as the electronic unit 152A and the electronic unit 152B) are respectively buried in the encapsulating material 153, but the present disclosure is not limited thereto. According to some embodiments, the encapsulating material 153 includes, for example, an epoxy molding compound (EMC), but the present disclosure is not limited thereto. By the arrangement of the encapsulating material 153, it is helpful to reduce the contact or penetration of water vapor or oxygen into the corresponding components and improve the reliability of components or stacks, but the present disclosure is not limited thereto. According to some embodiments, the encapsulating material 153 may include an organic resin, an epoxy resin, an epoxy molding compound (EMC), ceramic, poly(methyl methacrylate) (PMMA), polydimethylsiloxane (PDMS), other suitable materials, or a combination of the above materials, but the present disclosure is not limited thereto.

Please continue to refer to FIG. 6, a cutting step may be carried out corresponding to the second opening 132O to divide the circuit structure 130 into at least two circuit units (for example, the circuit unit 141 and the circuit unit 142). For example, after the packaging step is completed, the structure may be subjected to a singulation step to separate a plurality of packaged electronic units (such as the circuit unit 141 and the circuit unit 142). According to some examples, the adjacent electronic units 152A and 152B may be separated by cutting along the cutting line 103. As shown in FIG. 6, the substrate 110 and/or the warpage anti layer 111 may be removed before (or after) the singulation step, and then the seed layer 131S may be removed to obtain a single circuit unit (such as the circuit unit 141 or the circuit unit 142). If necessary, the bonding elements 151-1 may be disposed on a side of the circuit unit 141 (or the circuit unit 142) away from the electronic unit 152A (or from the electronic unit 152B). These bonding elements 151-1 may be respectively electrically connected to the corresponding circuit units (the circuit unit 141 and the circuit unit 142) to substantially complete an electronic device having a package structure unit, but the present disclosure is not limited thereto. In some embodiments, the second opening 132O may substantially correspond to or overlap the non-device region 102-1 (i.e., the region between adjacent device regions 102). The non-device region 102-1 may correspond to or overlap the laser-opening region, and the laser opening region may correspond to or overlap the cutting line 103.

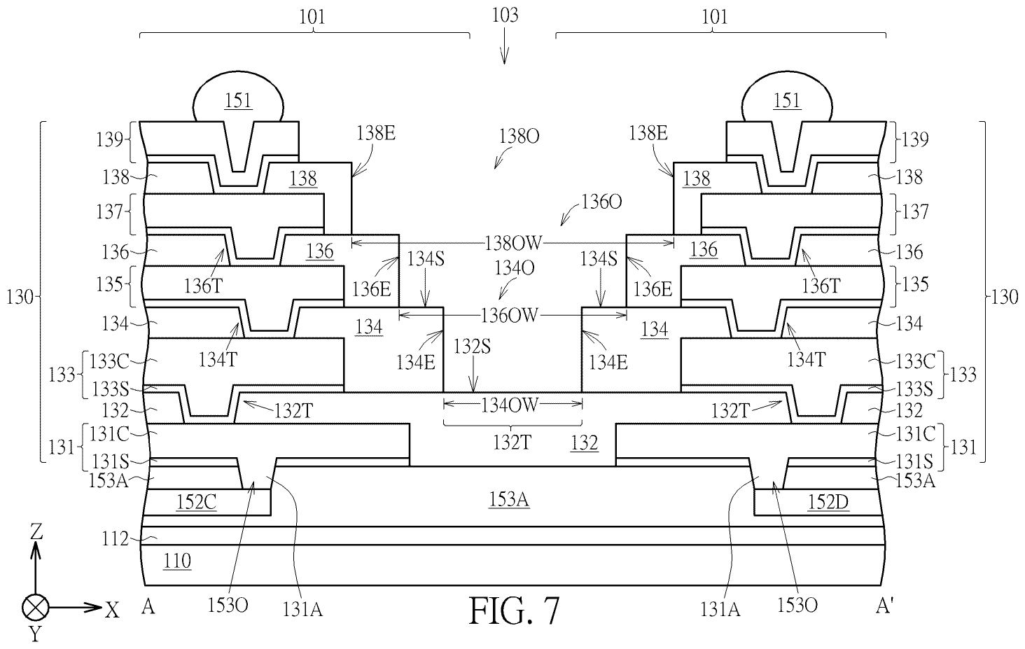

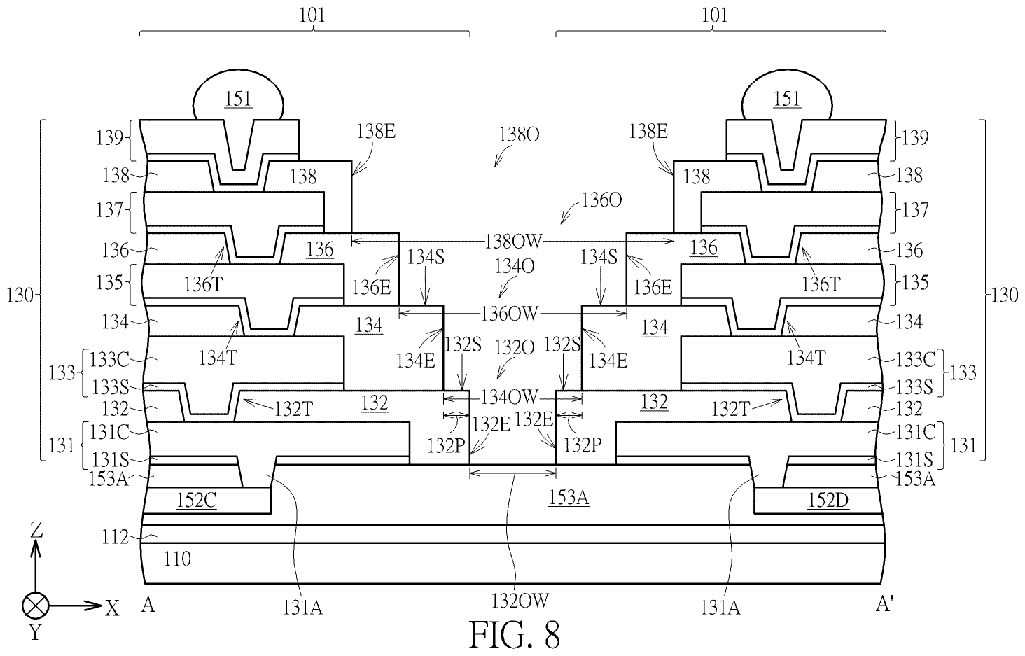

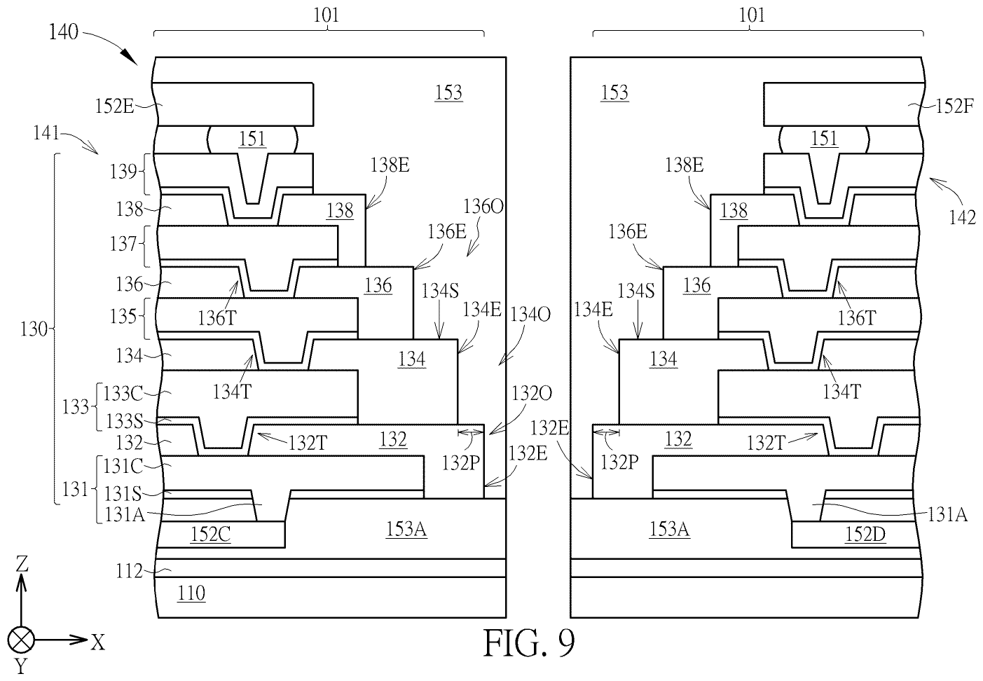

FIG. 7 to FIG. 9 respectively illustrate a schematic diagram of a variant embodiment of a method of forming an electronic device according to the present disclosure, in which a chip first packaging method is provided. FIG. 7, FIG. 8, and FIG. 9 respectively illustrate a component structure in a cross-sectional schematic diagram. For example, in FIG. 7, the electronic units (electronic unit 152C and electronic unit 152D) are first disposed in the encapsulating material 153A, and then the above-mentioned pile structure is disposed on the substrate 110 and on the release layer 112. Subsequently, the first conductive layer 131 is disposed on the electronic units (electronic unit 152C and electronic unit 152D) and on the encapsulating material 153A. The electronic units (electronic unit 152C and electronic unit 152D) and the encapsulating material 153A are, for example, disposed between the first conductive layer 131 and the release layer 112 (or the substrate 110). In some embodiments (not shown), a warpage anti layer 111 (not shown in FIG. 7) may be optionally disposed between the substrate 110 and the release layer 112. For example, the encapsulating material 153A has a plurality of openings 1530 corresponding to or overlapping the electronic units (electronic unit 152C and electronic unit 152D). A plurality of openings 1530 may respectively expose a portion of the electronic units (electronic unit 152C and electronic unit 152D), for example the pads (not labeled) of the electronic units (electronic unit 152C and electronic unit 152D) are exposed, to be electrically connected to the first conductive layer 131 via the pads (not labeled) of the electronic units (electronic unit 152C and electronic unit 152D). Similar to the above-mentioned method shown in FIG. 2, the first insulating layer 132, the second conductive layer 133, the second insulating layer 134, the third conductive layer 135, the third insulating layer 136, the top conductive layer 137, the top insulating layer 138 and the bonding conductive layer 139 are subsequently disposed to complete the arrangement of the circuit structure 130, but the present disclosure is not limited thereto, and a conductive layer and an insulating layer may be added or omitted according to requirements. The method of disposing the circuit structure 130 includes carrying out a first patterning step on the second insulating layer 134 to form a first opening 134O, and the first opening 134O may expose a portion 132T of the first insulating layer 132. Similarly, the manufacturing method may further include carrying out a third patterning step on the third insulating layer 136 to form the third opening 136O. In a cross-section of the electronic device, the third opening 136O overlaps the first opening 134O, the width 136OW of the third opening 136O may be greater than the width 134OW of the first opening 134O, and the third opening 136O may optionally expose a portion of an upper surface 134S of the second insulating layer 134. As shown in FIG. 8, please refer to FIG. 3, a second patterning step is carried out on the portion 132T of the first insulating layer 132 exposed by the first opening 134O to form a second opening 132O. In a cross-section of the electronic device, the second opening 132O overlaps the first opening 134O, the width 132OW of the second opening 132O is smaller than the width 134OW of the first opening 134O, and the first opening 134O exposes a portion (such as the portion 132T) of the upper surface 132S of the first insulating layer 132. Subsequently, for example, the bonding elements 151 are disposed on the bonding conductive layer 139 of the circuit structure 130 so that the bonding elements 151 are electrically connected to the bonding conductive layer 139. Then, as shown in FIG. 9, the electronic unit 152E and the electronic unit 152F are electrically connected to different bonding conductive layers 139 via different bonding elements 151 respectively. Please refer to the above for the details of the bonding element 151. As shown in FIG. 9, in some embodiments, the encapsulating material 153 may be disposed on the circuit structure 130 and on the electronic unit (such as the electronic unit 152E and the electronic unit 152F), and in a cross-section, the encapsulating material 153 may, for example, contact at least one side 132E of the first insulating layer 132, at least one side 134E of the second insulating layer 134, at least one side 136E of the third insulating layer 136, and/or at least one side 138E of the top insulating layer 138. Please refer to the above for the details of the encapsulating material 153. According to some embodiments, the encapsulating material 153 may cover the circuit structure 130, a plurality of bonding elements 151 and a plurality of electronic units (such as the electronic unit 152E and the electronic unit 152F), so that the circuit structure 130, the bonding elements 151 and the electronic units (such as the electronic unit 152E and the electronic unit 152F) are respectively buried in the encapsulating material 153, but the present disclosure is not limited thereto. According to some embodiments, the encapsulating material 153 includes, for example, an epoxy molding compound, but the present disclosure is not limited thereto. Please refer to the above for the materials for the encapsulating material 153. The disposition of the encapsulating material 153 is beneficial to reduce the contact or penetration of water vapor or oxygen into the corresponding components and improve the reliability of the components or the pile structure.

Please continue to refer to FIG. 9. A cutting step may be carried out to correspond to the second opening 132O to divide the circuit structure 130 into at least two circuit units. For example, after the packaging step is completed, the structure may be subjected to a singulation step to separate a plurality of packaged electronic units (such as the adjacent electronic unit 152E and the electronic unit 152F), or separate several electronic units (such as the adjacent electronic unit 152C and the electronic unit 152D). Subsequently (not shown), the substrate 110 and the release layer 111 may be optionally removed before or after the singulation step to roughly complete the electronic device having the package structure unit. In some examples, the second opening 132O may correspond to or overlap the non-device region 102-1 (i.e., the non-device region 102-1 between the device regions 102). The non-device region 102-1 may correspond to or overlap the laser opening region, and the laser opening region may correspond to or overlap the cutting line 103.

In summary, the main differences between the structures shown in FIG. 9 and in FIG. 6 reside in the different arrangement positions and/or the connection relationship of the adjacent electronic units 152C and 152D in FIG. 9 and of the adjacent electronic units 152A and 152B in FIG. 6. In addition to the electronic unit 152E and the electronic unit 152F provided to correspond to the bonding elements 151 in FIG. 9, an electronic unit 152C and an electronic unit 152D may be further pre-disposed in the encapsulating material 153A. The encapsulating material 153A and the encapsulating material 153 may be in contact with each other. The materials of the encapsulating material 153A and of the encapsulating material 153 may be the same as or different from each other. Please refer to the above for the materials.

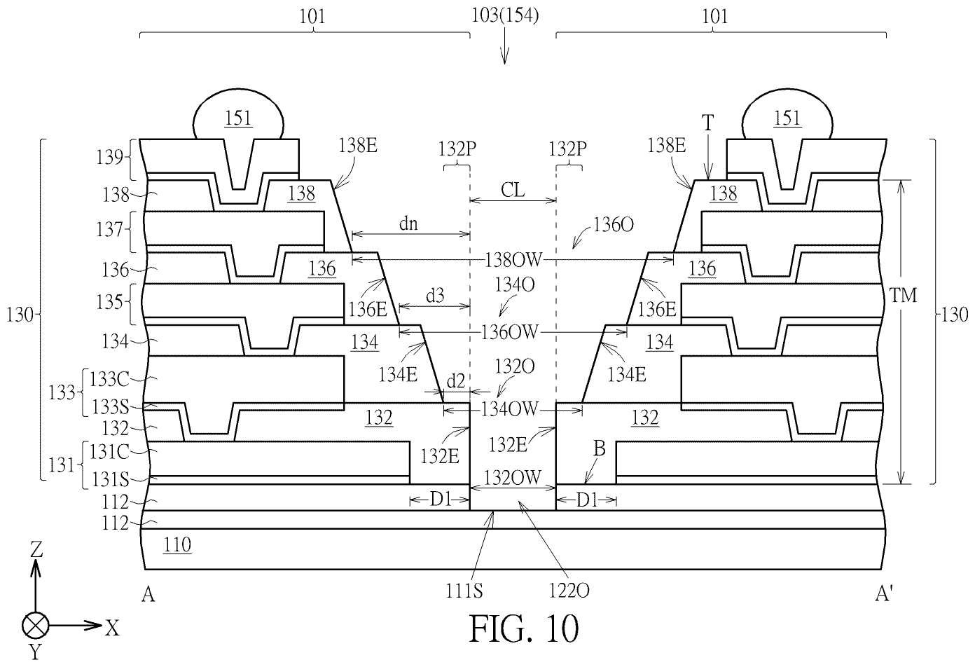

Please continue to refer to FIG. 10. FIG. 10 illustrates a partial flow diagram of a process corresponding to some methods of forming an electronic device of the present disclosure. The structural differences between FIG. 10 and FIG. 3 reside in optional inclined sides in a cross-section (for example, a cross-section along the X direction or along the Y direction) of each insulating layer of the circuit structure 130 in FIG. 10, and for example substantially vertical sides in a cross-section (for example, a cross-section along the X direction or along the Y direction) of each insulating layer of the circuit structure 130 in FIG. 3. In other embodiments, some partial vertical sides or some partial inclined sides in a cross-section (for example, a cross-section along the X direction or along the Y direction) of each insulating layer of the circuit structure 130 are possible. According to some embodiments, in a cross-section (for example, a cross-section along the X direction), at least a portion 132P of the first insulation layer 132 adjacent to the second opening 132O may have a width D1 along the X direction. Taking the process tolerance and/or the production capacity of the package structure unit into consideration, the width D1 may be greater than 0 and less than 6 millimeters (mm) (0<D1<6 mm), but the present disclosure is not limited thereto. According to some embodiments, the width D1 is, for example, greater than or equal to 1 mm and less than or equal to 5 mm (1 mm≤D1≤5 mm), or greater than or equal to 1 mm and less than or equal to 4 mm (1 mm≤D1≤4 mm), or greater than or equal to 1 mm and less than or equal to 3.5 mm (1 mm≤D1≤3.5 mm), but the present disclosure is not limited thereto. Similarly, according to some embodiments (not shown), at least a portion 132P of the first insulation layer 132 adjacent to the second opening 132O may have a width (not shown) along the Y direction. Taking the process tolerances and/or the production capacity of the packaging structure unit into consideration, the width (not labeled) of the portion 132P of the insulating layer 132 along the Y direction may be greater than 0 and less than 6 mm (0<width<6 mm), but the present disclosure is not limited thereto. It should be noted that the portion 132P of the first insulating layer 132 in FIG. 10 (or in other cross-sections) is, for example, divided into two portions 132P on the left and on the right adjacent to the second opening 132O. The widths D1 of the two left and right portions 132P along the X direction may be the same or different from each other. Similarly, in a cross-section (for example, a cross-section along the Y direction), the portion 132P of the first insulating layer 132 is divided into two portions 132P on the left and on the right adjacent to the second opening 132O. The widths D1 of the two portions 132P on the left and on the right along the Y direction may be the same or different from each other.

Please continue to refer to FIG. 10. After a second patterning step is carried out on a portion 132P (not shown in FIG. 10 but please refer to FIG. 2) of the first insulating layer 132 which is exposed by the first opening 134O to form the second opening 132O, in a cross-section of the electronic device (for example, a cross-section along the X direction), there may be a minimal distance d2 along the X direction between at least one side 134E of the second insulation layer 134 adjacent to the second opening 132O and at least one side 132E of the first insulation layer 132. Similarly, in the cross-section, there may be a minimal distance d3 along the X direction between at least one side 136E of the third insulating layer 136 adjacent to the second opening 132O and at least one side 132E of the first insulating layer 132. According to some embodiments, twice the first distance d2 may be equal to the second distance d3, that is, 2×d2=d3, but the present disclosure is not limited thereto. The relationship between the minimal distance d3 and the minimal distance d2 may be adjusted according to the requirements. According to some embodiments, twice the first distance d2 may be not equal to the second distance d3, that is, 2×d2+d3.

In a similar fashion, in a cross-section of the electronic device (for example, a cross-section along the X direction), there may be has a minimal distance dn along the X direction between at least one side of the n^{th} insulating layer adjacent to the second opening 132O and at least one side 132E of the first insulating layer 132. In some examples, the circuit structure 130 for example includes n-layer insulating layers, and the n^{th} insulating layer may be referred to the top insulating layer 138. At this time, in a cross-section (for example, a cross-section along the X direction), there is a minimal distance dn along the X direction between the side 138E of the top insulating layer 138 and at least one side 132E of the first insulating layer 132, the minimal distance dn may be greater than or equal to the minimal distance d2, and the minimal distance d2 is greater than 0, but the present disclosure is not limited thereto. The relationship between the minimal distance d2 and the minimal distance dn may be adjusted according to the requirements. In some embodiments, the minimal distance dn may be greater than or equal to 1 μm (dn≥1 μm), or may be greater than or equal to 1.5 μm (dn≥1.5 μm), or may be greater than or equal to 2 μm (dn≥2 μm), but the present disclosure is not limited thereto. In some examples (not shown), in a cross-section (for example, a cross-section along the X direction or along the Y direction), a minimal distance between at least one side of each insulation layer (excluding the first insulation layer 132) of the circuit structure 130 and at least one side of the first insulation layer 132 may be the same as each other (d2=d3=dn) or at least partially the same (for example, d2=d3, dn>d2, but the present disclosure is not limited thereto). When d2=d3=dn, it means that the side 134E, the side 136E and the side 138E are roughly aligned with one another.

According to some embodiments, in a cross-section (for example, a cross-section along the X direction or along the Y direction), a minimal pitch distance between at least one side of adjacent insulating layers in the circuit structure 130 adjacent to the second opening 132O may, for example, approximately equally withdraw. For example, d3−d2=dn−dn−1 and so on, but the present disclosure is not limited thereto. According to some embodiments, a minimal pitch distance between at least one side of adjacent insulating layers in the circuit structure 130 adjacent to the second opening 132O, for example, may not approximately equally withdraw. For example, d3−d2+dn−dn−1 and so on. According to some embodiments, the adhesion between the first insulating layer 132 and the release layer 112 may be higher than that between the seed layer 131 and the release layer 112 because the materials of the first insulating layer 132 and those of the release layer 112 in the circuit structure 103 may have similar properties or similar compositions. It may be helpful to increase the adhesion between the circuit structure 230 and the release layer 112 when the first insulating layer 132 adjacent to the second opening 132O is at least partially in contact with the release layer 112. In other words, by designing the portion 132P of the first insulation layer 132 adjacent to the second opening 132O to have a width D1 along the X direction, and the width D1 greater than 0 and less than 6 mm, it may be helpful to increase the adhesion between the circuit structure 230 and the release layer 112. Similarly (not shown), by designing the portion 132P of the first insulation layer 132 adjacent to the second opening 132O to have a width (not shown) along the Y direction (or other directions perpendicular to the Z direction), and the width (not shown) greater than 0 and less than 6 mm, it may be helpful to improve the adhesion between the circuit structure 230 and the release layer 112. In addition, by designing the relationships between the minimal distance d2, the minimal distance d3 and the minimal distance dn, for example, the minimal distance d2, the minimal distance d3 and the minimal distance dn are designed to be different from one another, or at least partially different from one another, the warpage stress of the circuit structure 130 which is generated during the manufacturing process may be further distributed, to reduce the peeling caused by the stacking of the warpage stress between the circuit structure 130 and the release layer 112, thereby improving the structural stability of the electronic device. It should be noted that, as shown in FIG. 10, in a cross-section (for example, a cross-section along the X direction), the first insulation layer 132, the second insulation layer 134, the third insulation layer 136 and the top insulation layer 138 adjacent to the second opening 132O may be divided into a left part and a right part. In a cross-section (for example, a cross-section along the X direction), there is a minimal distance d2 respectively disposed between the left part and the right part of the side 134E of the second insulating layer 134, of the side 132E of the first insulating layer 132 along the X direction. The minimal distance d2 of the left part and the right part may be equal to each other or unequal to each other. Similarly, in a cross-section (for example, a cross-section along the X direction), there is a minimal distance d3 respectively disposed between the left part and the right part of one side 136E of the third insulating layer 136 and of the side 132E of the first insulating layer 132 along the X direction. The minimal distance d3 of the left part and the right part may be equal to each other or unequal to each other. Similarly, in a cross-section (for example, a cross-section along the X direction), there is a minimal distance dn respectively disposed between the left part and the right part of the side 138E of the top insulating layer 138 and of the side 132E of the first insulating layer 132 along the X direction. The minimal distance dn of the left part and the right part may be equal to each other or unequal to each other.

Table 1 is a stress simulation comparison table of some embodiments of the present disclosure, for example, a stress simulation comparison table of a conventional structure (that is, d2˜dn=0), of Embodiment 1 (withdrawal of one single layer, that is, d2>0, and d2˜dn are equal to one another), and of Embodiment 2 (withdrawal of every layer, that is, dn>dn−1 . . . >d2, and d2>0). Embodiment 2 (withdrawal of every layer) for example shows that the multiple insulating layers in the circuit structure 130 all withdraw, and for example, dn−dn−1= . . . =d3−d2=d, d is for example in a range greater than 0 and smaller than or equal to 1000 μm, and d2 is for example in a range greater than 0 and smaller than or equal to 1000 μm, but the present disclosure is not limited thereto. The value of d may be adjusted according to requirements, for example, d may be in a range between 50 μm and 2500 μm or may be in a range between a range of 100 μm and 2000 μm, but the present disclosure is not limited thereto. Withdrawal of one single layer means that d2=d>0 in the circuit structure 130, d is, for example, in a range greater than 0 and smaller than or equal to 1000 μm, and d2˜dn are equal to one another (that is, the sides from the second insulating layer to the n^{th} insulating layer approximately align with one another). The value of d as mentioned above may be adjusted according to requirements. P1, P2, P3 and P4 in the table respectively represent the stress simulation results of the bottoms of the sides from the first insulating layer to the fourth insulating layer corresponding to different structures. In addition, poor or good in the table are examples of peeling after warpage which corresponds to the sides of different layers in different structures. Good means that no peeling after warpage is observed regarding this layer, and poor means that undesirable peeling after warpage occurs and is observed regarding this layer. According to the results shown in Table 1, compared with the conventional structure, withdrawal of one single layer and withdrawal of every layer both have significant improvements on the degree of warpage (that is, the degree of warpage is therefore reduced).

TABLE 1

| | | | | | degree of |
|---|---|---|---|---|---|
| | P1 | P2 | P3 | P4 | warpage |
| conventional structure(that is, | poor | good | good | good | severe |
| d2~dn = 0) | | | | | |
| Embodiment 1 (withdrawal of | good | good | good | good | not serious |
| one single layer) | | | | | |
| Embodiment 2 (withdrawal of | good | good | good | good | not serious |
| every layer) | | | | | |

Please continue to refer to FIG. 10. In a cross-section (for example, a cross-section along the X direction), a plurality of the insulating layers (for example, the first insulation layer 132, the second insulation layer 134, the third insulation layer 136 and the top insulation layer 138) in the circuit structure 130 may be divided into a left part and a right part. At least one of the left part and the right part, there may be a distance TM along the Z direction between the bottom surfaces B (for example, the bottom surface of the top insulation layer 138) of a plurality of insulating layers in the circuit structure 130 and the top surface T (for example, the top surface of the top insulation layer 138) of a plurality of insulating layers in the circuit structure 130. In some examples, the minimal distance dn along the X direction between the side 138E of the n^{th} insulating layer (for example, the top insulating layer 138) and the side 132E of the first insulating layer 132 may be greater than or equal to the distance TM (dn≥TM). In some examples (not shown), the minimal distance dn along the Y direction between the side 138E of the above n^{th} insulating layer (for example, the top insulating layer 138) and the side 132E of the first insulating layer 132 may be greater than or equal to the distance TM (dn>TM).

In a cross-section (for example, a cross-section along the X direction or along the Y direction), the first opening 132O has a width CL along the X direction (or the Y direction), and the first opening 132O approximately corresponds to or overlaps the cutting line 103. In some examples, the width CL may be greater than or equal to 300 μm and less than or equal to 1500 μm (300 μm≤CL≤1500 μm), or greater than or equal to 400 μm and less than or equal to 1200 μm (400 μm≤CL≤1200 μm), or greater than or equal to 600 μm and less than or equal to 1000 μm (600 μm≤CL≤1000 μm), but the present disclosure is not limited thereto.

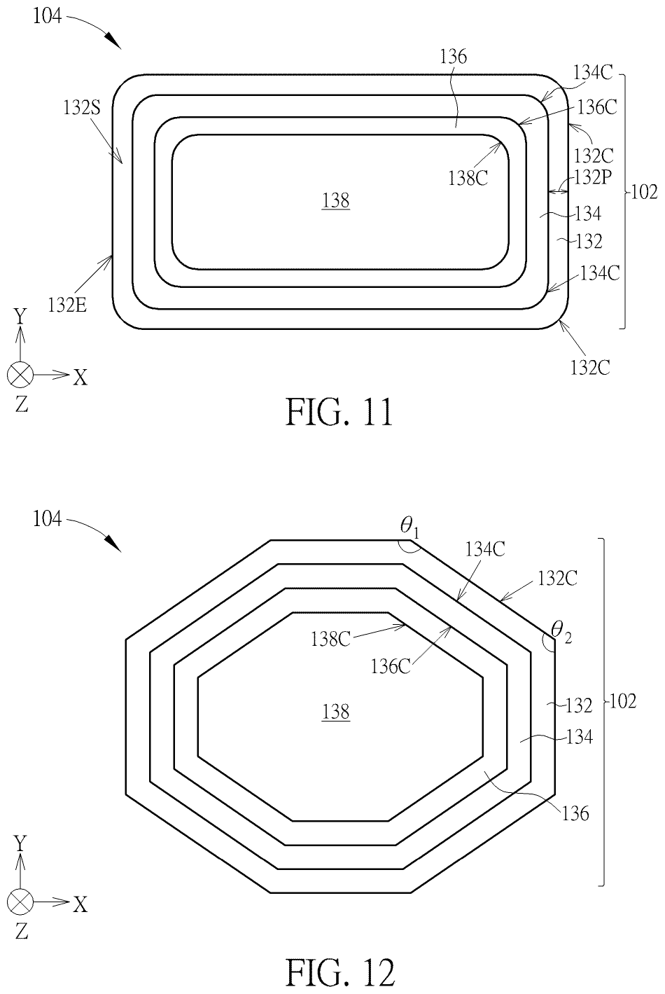

FIG. 11 to FIG. 13 respectively illustrate a schematic top view of an electronic device of some embodiments of a method of forming the electronic device 104 according to the present disclosure. Please refer to FIG. 3, FIG. 4, FIG. 8 and FIG. 10 together. When viewing the X-Y plane of the electronic device the portion 132P of the first insulating layer 132 which is exposed by the first opening 134O forms the second opening 132O after the second patterning step is carried out, the multiple insulating layers in the circuit structure 130 may respectively have a contour when viewing the X-Y plane of the electronic device, such as the first insulating layer 132, the second insulating layer 134, the third insulating layer 136 and the top insulating layer 138 may respectively have a contour 132C, a contour 134C, a contour 136C and a contour 138C, but the present disclosure is not limited thereto. According to some embodiments, the shapes of at least two of a plurality of the contours (for example, the contour 132C, the contour 134C, the contour 136C and the contour 138C) may correspond to one another or may not correspond to one another. The corresponding of contour shapes includes similar shapes with or without the same size. As shown in FIG. 11, a plurality of the contours (for example, the contour 132C, the contour 134C, the contour 136C and the contour 138C) are, for example, in a form of a rectangular shape with a rounded corner, but the sizes of the contours are different (or at least partially different). This design may be referred to as an outline correspondence. As shown in FIG. 12, a plurality of the contours (for example, the contour 132C, the contour 134C, the contour 136C and the contour 138C), for example, have a polygonal (for example, an octagonal shape, but the present disclosure is not limited thereto) contour, but the sizes of the contours are different (or at least partially different). This design may also be referred to as an outline correspondence. In other embodiments (not shown), the contour 132C has, for example, a rectangular shape without a rounded corner, and the contour 134C, the contour 136C and/or the contour 138C has, for example, a rectangular shape with a rounded corner. This design may be referred to as a non-correspondence of the outline of the contour 132C with the contour 134C, with the contour 136C, and/or with the contour 138C. In some embodiments, at least one side of the contour 134C, of the contour 136C, and/or of the contour 138C may be optionally aligned or misaligned with one another.

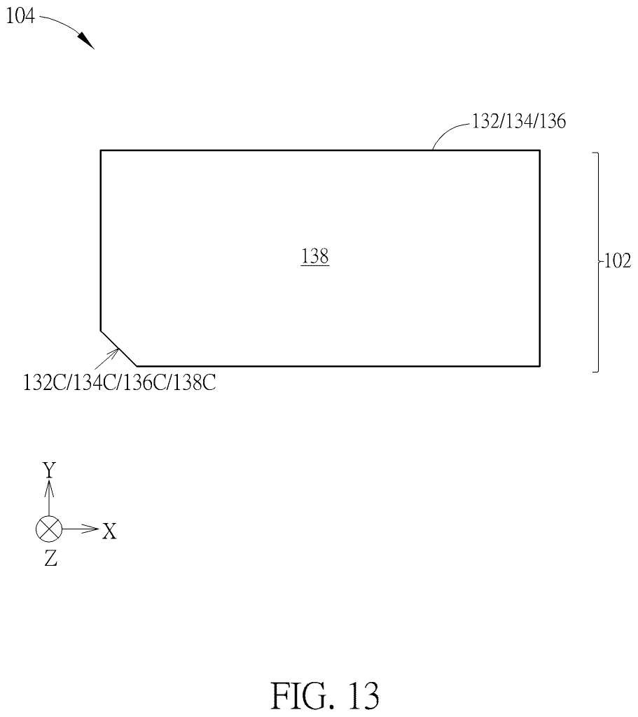

According to some embodiments of the present disclosure, from the direction of the top view of the electronic device at least one of the contour 132C, of the contour 134C, of the contour 136C and/or of the contour 138C may have an inclined side (as shown in FIG. 12) or an arc side (as shown in FIG. 11). FIG. 11 illustrates an embodiment in which the contour 132C, the contour 134C, the contour 136C and/or the contour 138C have arc sides which does not align with one another. FIG. 12 illustrates an embodiment in which the contour 132C, the contour 134C, the contour 136C and/or the contour 138C have arc sides which does not align. FIG. 13 illustrates an embodiment in which the contour 132C, the contour 134C, the contour 136C and/or the contour 138C have arc sides which align with one another, but the present disclosure is not limited thereto. From the direction of the top view of the electronic device, the design of the inclined side or the arc sides on the corners of the contours is helpful to reduce the stress at corners when at least a part of the contours of the multiple insulating layers in the circuit structure 130 has a design of the inclined side or the arc sides. From the direction of the top view of the electronic device, two adjacent sides of the contour 132C as shown in FIG. 12 have, for example, side angles (such as a side angle θ1 and a side angle θ2, but the present disclosure is not limited thereto). The degrees of the side angle θ1 and the degrees of the side angle θ2 may be the same as or different from each other. In some examples, the side angle θ1 and side angle θ2 may be greater than or equal to 100° and less than or equal to 170°, for example greater than or equal to 100° and less than or equal to 115°, greater than or equal to 100° and less than or equal to 125°, greater than or equal to 100° and less than or equal to 135°, greater than or equal to 100° and less than or equal to 145°, or greater than or equal to 100° and less than or equal to 155°, but the present disclosure is not limited thereto.

Table 2 is a stress simulation comparison table of some embodiments of the present disclosure, for example, a stress simulation comparison table of a conventional structure (that is, the corners of each insulation layer have right angles and do not withdraw (i.e., d2˜dn=0)), of Embodiment 3 (the corners of each insulation layer have inclined sides and do not withdraw (i.e., d2˜dn=0)), and of Embodiment 4 (the corners of each insulation layer have inclined sides (or arc sides) and withdraw, (i.e., dn>dn−1 . . . >d2, and d2>0). Embodiment 4 (the corners of each insulation layer have inclined sides and withdraw) for example shows that the multiple insulating layers in the circuit structure 130 all withdraw, and for example, with proportional withdrawal of dn−dn−1= . . . =d3−d2=d. For example d is in a range greater than 0 and smaller than or equal to 1000 μm, and d2 is for example in a range greater than 0 and smaller than or equal to 1000 μm, but the present disclosure is not limited thereto. The value of d may be adjusted according to requirements. P1, P2, P3 and P4 in the table respectively represent the stress simulation results of the bottoms of the sides from the first insulating layer to the fourth insulating layer corresponding to different structures. In addition, poor or good in the table are examples of peeling after warpage which corresponds to the sides of different layers in different structures. Good means that no peeling after warpage is observed regarding this layer, poor means that undesirable peeling after warpage occurs and is observed regarding this layer, and fair means that the peeling after warpage regarding this layer is acceptable. According to the results shown in Table 2, compared with the conventional structure, Embodiment 3 (the corners of each insulation layer have inclined sides and do not withdraw) and Embodiment 4 (the corners of each insulation layer have inclined sides and withdraw) both have significant improvements on the degree of warpage of the stacking layers (that is, the degree of warpage is therefore reduced).

TABLE 2

| | | | | | degree of |
|---|---|---|---|---|---|
| | P1 | P2 | P3 | P4 | warpage |
| conventional structure(the | poor | good | good | good | severe |
| corners of each insulation layer | | | | | |
| have right angles and do not | | | | | |
| withdraw) | | | | | |
| Embodiment 3 (the corners of | fair | good | good | good | not serious |
| each insulation layer have | | | | | |
| inclined sides and do not | | | | | |
| withdraw) | | | | | |
| Embodiment 4 (withdrawal of | good | good | good | good | not serious |
| every layer) | | | | | |

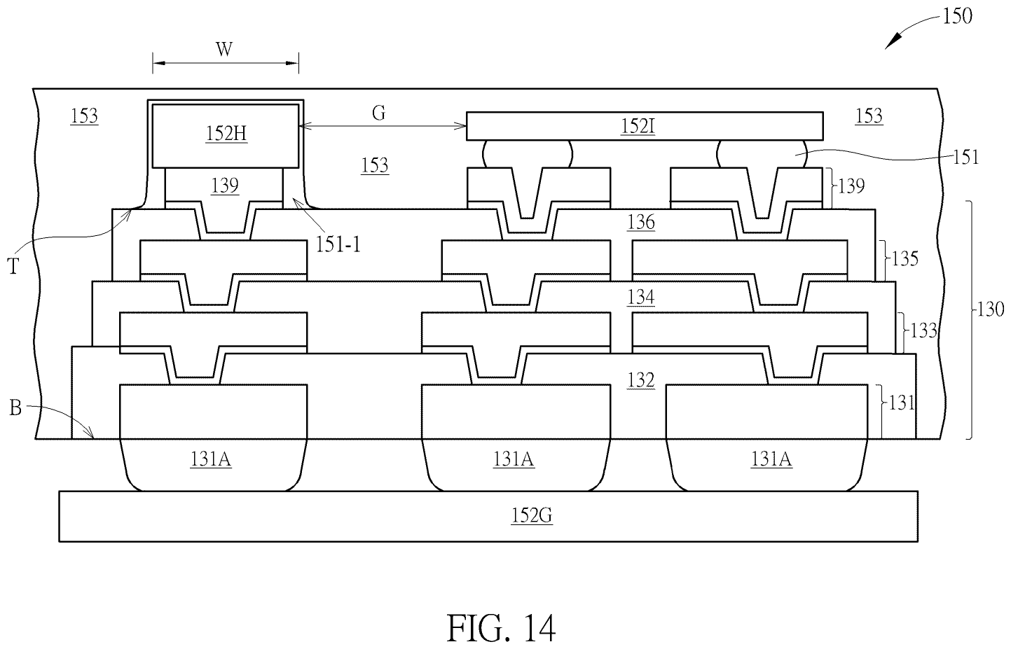

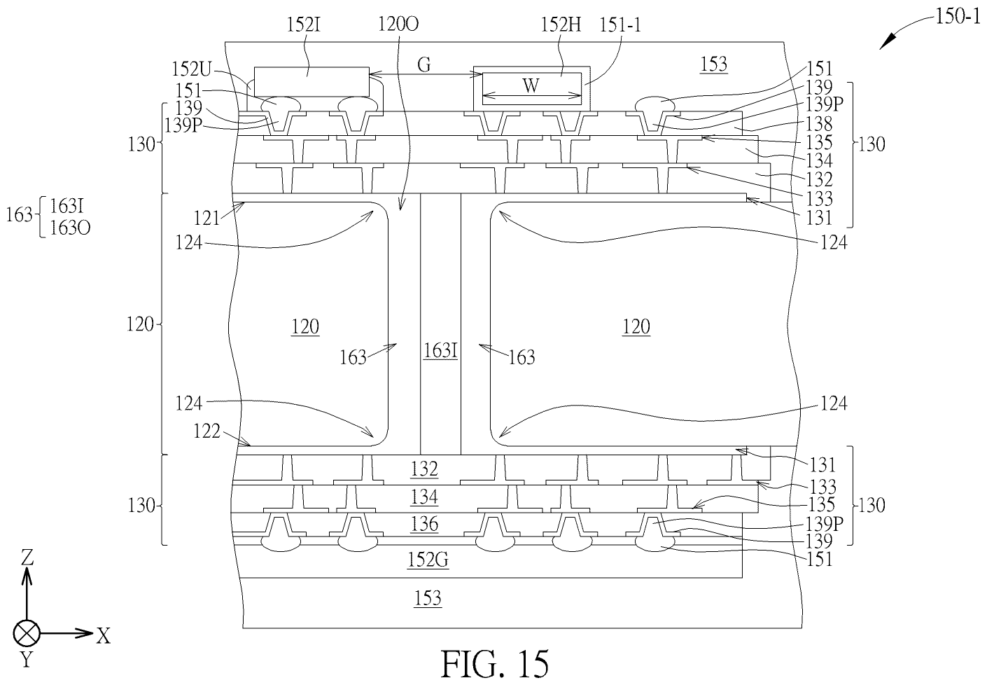

FIG. 14 illustrates a schematic process diagram of a method of forming an electronic device according to the present disclosure, and a schematic cross-sectional view illustrates the component structure. The package structure unit 150 shown in FIG. 14 may include various types of electronic units, such as an electronic unit 152G, an electronic unit 152H and an electronic unit 152I, but the present disclosure is not limited thereto. The electronic unit 152G and the electronic unit 152H (and/or the electronic unit 152I) may be respectively disposed on opposite sides of the circuit structure 130. The electronic unit 152G is, for example, adjacent to the bottom B of the circuit structure 130, and the electronic unit 152H (and/or the electronic unit 152I) is, for example, adjacent to the top surface T of the circuit structure 130, but the present disclosure is not limited thereto. The positional relationship of the electronic unit 152G and the electronic unit 152H (and/or the electronic unit 152I) may also be optionally exchanged. The electronic unit 152G, the electronic unit 152H, and the electronic unit 152I may respectively be electronic units of different functions. The electronic unit 152G may be electrically connected to the electronic unit 152H and to the electronic unit 152I via the circuit structure 130 and the connection element 131A. In some examples, the connection element 131A may be a bonding element formed by ball drop and reflow steps, but the present disclosure is not limited thereto. In some examples, the electronic unit 152G may include a printed circuit board (PCB) or other electronic components (driving components), but the present disclosure is not limited thereto. The electronic unit 152G may optionally include other active components (not shown) or passive components (not shown). The electronic unit 152H may include a surface mount component, which may include, for example, a capacitor, a resistor, or other suitable passive components, but the present disclosure is not limited thereto. The electronic unit 152I may include a die, a semiconductor element, a light-emitting diode, and a variable capacitance diode, but the present disclosure is not limited thereto. As shown in the figure, an underfill layer (not shown, but may refer to the underfill layer 152U in FIG. 15) may be optionally disposed around the conductive pad (not shown) connected to the electronic unit 152H or to the electronic unit 152I and to the circuit structure 130 and it is helpful to improve the reliability of the electronic unit 152H or of the electronic unit 152I. In some examples, the electronic unit 152H is electrically connected to the bonding conductive layer 139 via the bonding element 151-1, and the bonding element 151-1 may optionally extend to the side surface or to the upper surface (the surface away from the circuit structure 130) of the electronic unit 152H. In a cross-section (for example, a cross-section along the X direction), the electronic unit 152G may have a width W extending along the X direction, and there is a minimal distance G along the X direction (or Y direction) between the electronic unit 152G and the electronic unit 152I. In some examples, there is an arc-shaped edge where the bonding element 151-1 contacts the circuit structure 130 to improve the adhesion between the bonding element 151-1 and the circuit structure 130. In some examples, the bonding elements 151-1 may surround the corresponding bonding conductive layer 139. In some examples, the minimal distance G may be greater than or equal to the width W, that is, G≥W, thereby reducing the influence of undesirable electrical interference between the electronic unit 152G and the electronic unit 152I. In some examples, the ratio of the minimal distance G to the width W may be greater than 1 and less than or equal to 20. In some examples, the ratio of the minimal distance G to the width W may be greater than 1 and less than or equal to 15. In some examples, the ratio of the minimal distance G to the width W may be greater than 1 and less than or equal to 10. The advantages of the structure shown in FIG. 14 reside in the electrical connection of multiple different electronic units to increase the functions of the package structure unit 150. The number, location or type of different electronic units may be adjusted according to requirements.

FIG. 15 illustrates a schematic cross-sectional view of a variant embodiment of the electronic device. The electronic device shown in FIG. 15 includes a package structure unit 150-1. The package structure unit 150-1 may include a substrate 120. The substrate 120 may include an inorganic material layer or an organic material layer, such as a steel plate, glass, polyimide (PI), polyethylene terephthalate (PET), wafer, a copper substrate, other suitable materials or a combination of the above materials, but the present disclosure is not limited thereto. The substrate 120 may include a single layer structure or a multi-layer structure. The substrate 120 may have two opposite sides, such as a first side 121 and a second side 122 opposite the first side 121. Different circuit structures 130 may be respectively disposed on the first surface 121 and on the second surface 122 of the substrate 120. Please refer to the above for the details of the piles of the circuit structures 130. For example, the electronic unit 152H and the electronic unit 152I are adjacent to and electrically connected to the circuit structure 130 disposed on the first surface 121. Please refer to FIG. 14 for the types or details of the electronic unit 152H and of the electronic unit 152I. As shown in the figure, the electronic unit 152I (the conductive pad (not labeled) of the electronic unit 152) and the circuit structure 130 are electrically connected via the bonding element 151, and an underfill layer 152U may be optionally provided around the bonding element 151. The underfill layer 152U is helpful to improve the reliability of the bonding of the electronic unit 152I, and any suitable insulating material may be used for the underfill layer 152U. The underfill layer 152U may optionally contact side surfaces of electronic unit 152I. In some examples, the electronic unit 152H is electrically connected to the bonding conductive layer 139 via the bonding element 151-1, and the bonding element 151-1 may optionally extend to the side surface or to the upper surface (a surface away from the circuit structure 130) of the electronic unit 152H. In some embodiments, the encapsulating material 153 respectively provided on the first side 121 and on the second side 122 may cover and/or contact the circuit structure 130 and/or the electronic unit respectively. The bonding conductive layer 139 includes, for example, an under-bump metal layer (UBM), but the present disclosure is not limited thereto. The minimal distance G between the electronic unit 152H and the electronic unit 152I may be greater than or equal to the width W of the electronic unit 152H to be beneficial to reduce the undesirable influence of the electrical interference between the electronic unit 152H and the electronic unit 152I.

The substrate 120 illustrated in FIG. 15 may further include a through hole 1200 penetrating the substrate 120. A conductive material 163 may be disposed in the through hole 1200. The conductive layers of the conductive structure 130 disposed on the first surface 121 and on the second surface 122 may be electrically connected to each other via the conductive material 163, thereby a plurality of electronic units, such as the electronic unit 152G, the electronic unit 152H and the electronic unit 152I, electrically connected to one another. The conductive layer in the conductive structure 130 which is electrically connected to the conductive material 163 may, for example, be made of the same as or different conductive materials from that of the conductive material 163. The through hole 1200 may be regarded as a through glass via (TGV), a polyimide through hole (through PI via, TPV) or other suitable through holes, but the present disclosure is not limited thereto. In some embodiments, the through hole 1200 is formed, for example, by laser or other suitable methods. In some embodiments, the corner edges at the through holes 1200 of the substrate 120 may be curved edges or inclined edges, for example. The through hole 1200 may also be optionally filled with a material layer 163I, and the aforementioned conductive material 163 may, for example, surround the material layer 1631. The material layer 163I may include a conductive material, a non-conductive material, or a combination thereof, and the conductive material 163 may include a metal material, an alloy material, a transparent conductive material, or a combination thereof.

In some embodiments, the substrate 120 adjacent to the through hole 1200 of the first side 121 or of the second side 122 may have a corner 124. The corner 124 may include an oblique angle or an arc angle, but the present disclosure is not limited thereto. In some embodiments, the through hole 1200 overlaps the electronic unit 152H and the electronic unit 152I, for example. In some embodiments, the through hole 1200 overlaps the electronic unit 152G, for example. In some embodiments, the width of the through hole 1200 along the X direction is less than the above-mentioned minimal distance G, for example.

Some embodiments of the present disclosure provide a method of manufacturing an electronic device by the withdrawal of the second insulating layer 134 of the circuit structure 130 adjacent to the second opening 132O and relative to the first insulating layer 132, that is, the minimal distance d2 is designed to be greater than 0. It is helpful to distribute the stress caused by the upward warpage of the insulation layers in the circuit structure. In a cross-section, the width 132OW of the second opening 132O of the first insulating layer 132 is smaller than the width 134OW of the first opening 134O of the second insulating layer 134, the width 136OW of the third opening 136O of the third insulating layer 136 and/or the width 138OW of the opening 138O of the top insulating layer 138 to be helpful to distribute the stress of the upward warpage of each insulating layer in the circuit structure. Or, the structure of a part of the upper surface 132S of the first insulating layer 134 exposed by the first opening 134O, by the third opening 136O and/or by the opening 138O is helpful to distribute the stress of the upward warpage of each insulating layer in the circuit structure. In addition, in the top view direction, by designing the contours of the insulating layers of the circuit structure 130 at the corners to be inclined edges or arc edges, it is helpful to distribute the stress of the upward warpage of each insulating layer. In addition, in a cross-section, at least one side of adjacent each insulating layer in the circuit structure may have proportional withdrawal or have non-proportional withdrawal. The optional combinations of these different embodiments are helpful to reduce the possibility of undesirable peeling after warpage between the circuit structure (such as the seed layer) and the release layer, and to improve the structural stability and reliability.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method of manufacturing an electronic device, comprising:
providing a substrate;
disposing a release layer on the substrate;
disposing a circuit structure on the release layer, steps of disposing the circuit structure on the release layer comprising;
disposing a first conductive layer on the release layer;
disposing a first insulating layer on the first conductive layer and on the release layer;
disposing a second conductive layer on the first insulating layer to electrically connect the second conductive layer through a via of the first insulating layer to the first conductive layer;
disposing a second insulating layer on the second conductive layer; and
performing a first patterning step on the second insulating layer to form a first opening which exposes a portion of the first insulating layer; and
performing a second patterning step on the portion of the first insulating layer which is exposed by the first opening to form a second opening,
wherein in a cross-section of the electronic device, the second opening overlaps the first opening, a width of the second opening is smaller than a width of the first opening, and the first opening exposes an upper surface of the portion of the first insulating layer.

2. The method of manufacturing an electronic device of claim 1, wherein a method of the first patterning step and a method of the second patterning step are different.

3. The method of manufacturing an electronic device of claim 2, wherein the first patterning step uses a lithographic etching method, and the second patterning step uses a laser removal method.

4. The method of manufacturing an electronic device of claim 1, wherein a portion of the first insulating layer adjacent to the second opening contacts an upper surface of the release layer.

5. The method of manufacturing an electronic device of claim 4, wherein a width of the portion of the first insulating layer adjacent to the second opening is greater than 0 and less than 6 millimeters.

6. The method of manufacturing an electronic device of claim 1, wherein steps of disposing the circuit structure on the release layer further comprising:
disposing a third conductive layer on the second insulating layer, and the third conductive layer electrically connected to the second conductive layer through at least one via in the second insulating layer;
disposing a third insulating layer on the third conductive layer; and
performing a third patterning step on the third insulating layer to form a third opening, wherein in the cross-section of the electronic device, the third opening overlaps the first opening, a width of the third opening is greater than the width of the first opening, and the third opening exposes a portion of an upper surface of the second insulating layer.

7. The method of manufacturing an electronic device of claim 6, wherein in the cross-section of the electronic device, there is a first distance (d2) disposed between one side of the second insulating layer adjacent to the second opening and one side of the first insulating layer, there is a second distance (d3) disposed between one side of the third insulating layer adjacent to the second opening and the side of the first insulating layer, wherein 2 times of the first distance (d2) is equal to the second distance (d3) after performing the second patterning step on the portion of the first insulating layer exposed by the first opening to form the second opening.

8. The method of manufacturing an electronic device of claim 6, wherein in the cross-section of the electronic device, there is a first distance (d2) disposed between one side of the second insulating layer adjacent to the second opening and one side of the first insulating layer, there is a second distance (d3) disposed between one side of the third insulating layer adjacent to the second opening and the side of the first insulating layer, wherein 2 times of the first distance (d2) is not equal to the second distance (d3) after performing the second patterning step on the portion of the first insulating layer exposed by the first opening to form the second opening.

9. The method of manufacturing an electronic device of claim 1, wherein in the cross-section of the electronic device, at least one of a contour of the first insulating layer and a contour of the second insulating layer has an incline side or an arc side after performing the second patterning step on the portion of the first insulating layer exposed by the first opening to form the second opening.

10. The method of manufacturing an electronic device of claim 1, after performing the second patterning step on the portion of the first insulating layer exposed by the first opening to form the second opening further comprising:
performing a cutting step corresponding to the second opening to divide the circuit structure into at least two circuit units.

11. The method of manufacturing an electronic device of claim 1, before disposing the release layer on the substrate further comprising:
disposing a warpage anti layer on the substrate.

12. The method of manufacturing an electronic device of claim 1, wherein a surface of the release layer is treated with micro-etching.

13. The method of manufacturing an electronic device of claim 1, wherein the second patterning step partially removes the release layer to form an opening.

14. The method of manufacturing an electronic device of claim 13, wherein the opening overlaps the second opening.

15. The method of manufacturing an electronic device of claim 6, wherein the first insulating layer, the second insulating layer and the third insulating layer are sequentially disposed on the substrate and on the release layer to form one of a step-like pile structure and a pyramid-like pile structure.

16. The method of manufacturing an electronic device of claim 6, wherein from a top view direction of the electronic device, an area of the first insulating layer, an area of the second insulating layer and an area of the third insulating layer gradually decrease sequentially.

17. The method of manufacturing an electronic device of claim 16, wherein to gradually decrease is equally proportional or non-equally proportional.

18. The method of manufacturing an electronic device of claim 6, wherein at least one side of the second insulating layer exposed by the first opening aligns with at least one side of the third insulating layer exposed by the third opening.

19. The method of manufacturing an electronic device of claim 6, wherein a method of the third patterning step and a method of the second patterning step are different.

20. The method of manufacturing an electronic device of claim 6, wherein the third patterning step uses a lithographic etching method, and the second patterning step uses a laser removal method.
